(19) United States
(12) Patent Application Publication
(10) Pub. No.: US 2019/0182952 A1
(43) Pub. Date: Jun. 13, 2019

(54) SURFACE-MOUNT DEVICE

(71) Applicant: PEGATRON CORPORATION, TAIPEI CITY (TW)

(72) Inventor: Tzu-Lin Chen, Taipei City (TW)

(73) Assignee: PEGATRON CORPORATION, TAIPEI CITY (TW)

(21) Appl. No.: 16/198,592

(22) Filed: Nov. 21, 2018

(30) Foreign Application Priority Data
Dec. 8, 2017 (TW) 106143061

(51) Int. Cl. H05K 1/02; H05K 1/18

(52) U.S. Cl. CPC H05K 1/0292; H05K 2201/10363; H05K 1/181

(57) ABSTRACT

A surface-mount device includes a first electrode, a second electrode, a third electrode, a fourth electrode, a first impedance layer, and a second impedance layer. The first impedance layer is disposed between the first electrode and the second electrode, and is electrically connected to the first electrode and the second electrode in a first direction. The second impedance layer is disposed between the third electrode and the fourth electrode, and is electrically connected to the third electrode and the fourth electrode in a second direction perpendicular to the first direction, and the second impedance layer is interlaced with and electrically isolated with the first impedance layer.

### CROSS REFERENCE TO RELATED APPLICATION

This application claims the priority benefit of Taiwanese application serial no. 106143061, filed on Dec. 8, 2017. The entirety of the above-mentioned patent application is hereby incorporated by reference herein and made a part of specification.

### BACKGROUND

### Technology Field

The invention relates to a surface-mount device, and particularly related to a surface-mount device having interlacing routing.

### Description of the Related Art

With the development of semiconductor technology, routings on circuit boards have become more and more elaborate. Apart from applying through holes to interlace routings, multi-layer printed circuit boards also apply jumpers to interlace routings. However, single-layer printed circuit boards fail to apply a large number of through holes. Furthermore, the jumpers are not built in a device library, and are unable to directly plan the location of jumpers with routing tools. Therefore, the application of the jumpers may enhance the complexity of circuit design, and thus indirectly increases the inconvenience of circuit design.

### SUMMARY

The invention provides a surface-mount device having a property of interlacing routing, which simplifies the complexity of circuit design to reduce the inconvenience of circuit design.

A surface-mount device of the invention includes a first electrode, a second electrode, a third electrode, a fourth electrode, a first impedance layer, and a second impedance layer. The first impedance layer is disposed between the first electrode and the second electrode, and is electrically connected to the first electrode and the second electrode in a first direction. The second impedance layer is disposed between the third electrode and the fourth electrode and is electrically connected between the third electrode and the fourth electrode in a second direction perpendicular to the first direction, and the second impedance layer is interlaced with and electrically isolated from the first impedance layer.

In view of the above, the embodiment of the invention provides the surface-mount device having interlacing routing to provide a user with transferring from a device library. As such, the complexity of circuit design may be simplified, so as to reduce the inconvenience of circuit design. In addition, the overall thickness of the circuit board may not be affected.

To provide a further understanding of the aforementioned and other features and advantages of the disclosure, exemplary embodiments, together with the reference drawings, are described in detail below.

### BRIEF DESCRIPTION OF THE DRAWINGS

FIG. 1 is a schematic top view according to a surface-mount device of an embodiment of the invention.

FIG. 2A is a cross-sectional schematic diagram of a surface-mount device along line A-A′ according to a surface-mount device of an embodiment of the invention.

FIG. 2B is a cross-sectional schematic diagram of a surface-mount device along line B-B′ according to a surface-mount device of an embodiment of the invention.

### DETAILED DESCRIPTION

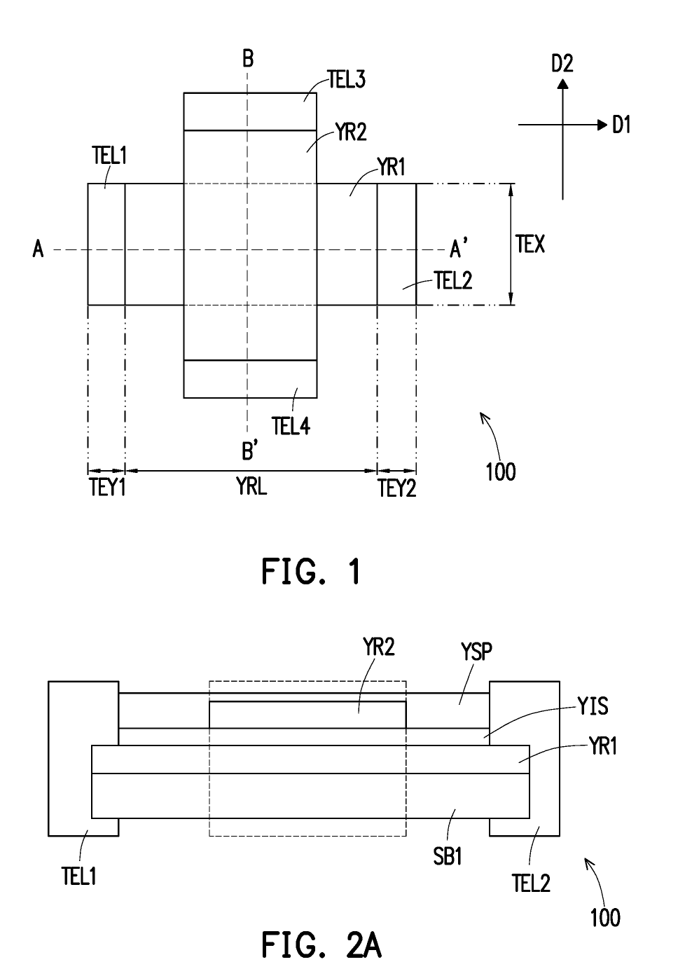

FIG. 1 is a schematic top view according to a surface-mount device of an embodiment of the invention. Referring to FIG. 1, in this embodiment, a surface-mount device 100 includes at least a first electrode TEL1, a second electrode TEL2, a third electrode TEL3, a fourth electrode TEL4, a first impedance layer YR1, and a second impedance layer YR2. The first impedance layer YR1 is disposed between the first electrode TEL1 and the second electrode TEL2, and is electrically connected to the first electrode TEL1 and the second electrode TEL2 in a first direction D1.

The second impedance layer YR2 is disposed between the third electrode TEL3 and the fourth electrode TEL4, and is electrically connected to the third electrode TEL3 and the fourth electrode TEL4 in a second direction D2 perpendicular to the first direction D1. Here, a routing direction (that is, an extension direction) of the second impedance layer YR2 is interlaced with a routing direction of the first impedance layer YR1 (that is, an extension direction), and the second impedance layer YR2 and the first impedance layer YR1 are electrically isolated.

In accordance with the above, the embodiment of the invention provides the surface-mount device 100 having an interlacing routing, in the device library for the user. As such, the complexity of circuit design may be simplified, so as to reduce the inconvenience of circuit design.

In addition, in an embodiment, the surface-mount device 100 may be compliant with 0402SMT element regulation. That is, the width (labeled as TEX) of an electrode (for example, the first electrode TEL1, the second electrode TEL2, the third electrode TEL3, the fourth electrode TEL4) is approximately 0.5 mm. The length (labeled as TEY1 and TEY2) of the electrode (for example, the first electrode TEL1, the second electrode TEL2, the third electrode TEL3, the fourth electrode TEL4) is approximately 0.635 mm. The shortest distance (for example, YRL) between the corresponding opposite electrodes (for example, the first electrode TEL1 and the second electrode TEL2, or the third electrode TEL3 and the fourth electrode TEL4) is approximately 0.635 mm, and the distance (for example, TEY1+YRL+TEY2) between the outside of the corresponding opposite electrodes (for example, the first electrode TEL1 and the second electrode TEL2, or the third electrode TEL3 or the fourth electrode TEL4) is approximately 1.905 mm.

In an embodiment, the surface-mount device 100 may be compliant with 0603SMT element regulation. That is, the width (labeled as TEX) of the electrode (for example, the first electrode TEL1, the second electrode TEL2, the third electrode TEL3, the fourth electrode TEL4) is approximately 0.8 mm. The length (labeled as TEY1 and TEY2) of the electrode (for example, the first electrode TEL1, the second electrode TEL2, the third electrode TEL3, the fourth electrode TEL4) is approximately 0.965 mm. The shortest distance (for example, YRL) between the corresponding opposite electrodes (for example, the first electrode TEL1 and the second electrode TEL2, or the third electrode TEL3 and the fourth electrode TEL4) is approximately 0.635 mm, and the distance (for example, TEY1+YRL+TEY2) between the outside of the corresponding opposite electrodes (for example, the first electrode TEL1 and the second electrode TEL2, or the third electrode TEL3 or the fourth electrode TEL4) is approximately 2.565 mm.

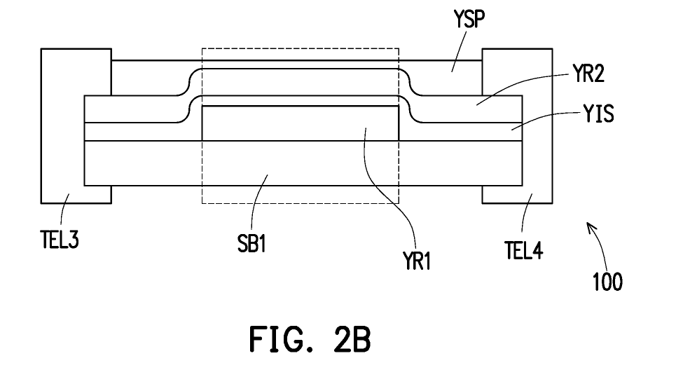

FIG. 2A is a cross-sectional schematic diagram of a surface-mount device along line A-A′ according to a surface-mount device of an embodiment of the invention shown in FIG. 1. FIG. 2B is a cross-sectional schematic diagram of a surface-mount device along line B-B′ according to a surface-mount device of an embodiment of the invention shown in FIG. 1. Referring to FIG. 1, FIG. 2A, and FIG. 2B, in this embodiment, the surface-mount device 100 further includes a substrate SB1, an isolation layer YIS, and a heat resistance layer YSP. The substrate SB1 is used to support the first impedance layer YR1, the second impedance layer YR2, the isolation layer YIS, and the heat resistance layer YSP. Starting from the substrate SB1, the first impedance layer YR1 is disposed on the substrate SB1, the isolation layer YIS is disposed on the first impedance layer YR1, the second impedance layer YR2 is disposed on the isolation layer YIS, and the heat resistance layer YSP is disposed on the second impedance layer YR2 and the isolation layer YIS.

As mentioned above, the isolation layer YIS is disposed between the first impedance layer YR1 and the second impedance layer YR2 to be electrically isolated the first impedance layer YR1 from the second impedance layer YR2. The heat resistance layer YSP covers the first impedance layer YR1, the second impedance layer YR2, and the isolation layer YIS, so as to prevent the first impedance layer YR1, the second impedance layer YR2, and the isolation layer YIS from being exposed.

As illustrated in FIG. 2A, the first electrode TEL1 and the second electrode TEL2 sandwich the substrate SB1 and the first impedance layer YR1, and both are electrically connected with the first impedance layer YR1. In addition, the first electrode TEL1 and the second electrode TEL2 are fixed to respective ends of the substrate SB1 and the first impedance layer YR1. As illustrated in FIG. 2B, the third electrode TEL3 and the fourth electrode TEL4 sandwich the substrate SB1, the isolation layer YIS and second impedance layer YR2, and both are electrically connected with the second impedance layer YR2. In addition, the third electrode TEL3 and the fourth electrode TEL4 are fixed to respective ends of the isolation layer YIS and the second impedance layer YR2.

In summary of the above, the embodiment of the invention provides a surface-mount device having an interlacing routing in the device library for the user. As such, the complexity of the circuit design may be simplified, so as to reduce the inconvenience of circuit design, and the total thickness of a circuit board will not be affected.

Although the invention is disclosed as the embodiments above, the embodiments are not meant to limit the invention. Any person skilled in the art may make slight modifications and variations without departing from the spirit and scope of the invention. Therefore, the protection scope of the invention shall be defined by the claims attached below.

What is claimed is:

1. A surface-mount device, comprising:
a first electrode;
a second electrode;
a first impedance layer, disposed between the first electrode and the second electrode, electrically connected to the first electrode and the second electrode in a first direction;
a third electrode;
a fourth electrode; and
a second impedance layer, disposed between the third electrode and the fourth electrode, electrically connected to the third electrode and the fourth electrode in a second direction perpendicular to the first direction, and the second impedance layer is interlaced with and electrically isolated from the first impedance layer.

2. The surface-mount device according to claim 1, further comprising a substrate, for supporting the first impedance layer and the second impedance layer.

3. The surface-mount device according to claim 2, further comprising an isolation layer, disposed between the first impedance layer and the second impedance layer.

4. The surface-mount device according to claim 3, further comprising a heat resistance layer, covering the first impedance layer and the second impedance layer.

5. The surface-mount device according to claim 3, wherein the first electrode and the second electrode sandwich the substrate and the first impedance layer.

6. The surface-mount device according to claim 3, wherein the third electrode and the fourth electrode sandwich the substrate, the isolation layer and the second impedance layer.

7. The surface-mount device according to claim 3, wherein the surface-mount device is compliant with 0402 or 0603SMT element regulation.
